(19) United States
(12) Patent Application Publication
(10) Pub. No.: US 2026/0066851 A1
(43) Pub. Date: Mar. 5, 2026

(54) SEMICONDUCTOR DEVICE AND DOHERTY AMPLIFIER

(71) Applicant: SUMITOMO ELECTRIC INDUSTRIES, LTD., Osaka (JP)

(72) Inventor: Ken KIKUCHI, Osaka (JP)

(21) Appl. No.: 19/290,864

(22) Filed: Aug. 5, 2025

(30) Foreign Application Priority Data
Sep. 2, 2024 (JP) 2024-150900

(51) Int. Cl. H03F 1/02; H03F 1/56; H10D 30/47; H10D 62/85; H10D 64/00

(52) U.S. Cl. CPC H03F 1/0288; H03F 1/56; H10D 30/471; H10D 62/8503; H10D 64/112

(57) ABSTRACT

A semiconductor device for a Doherty amplifier includes a main amplifier including a first field effect transistor, and includes a peak amplifier including a second field effect transistor. A first drain conductance of the first field effect transistor when applying a gate voltage obtained by adding a predetermined voltage to a pinch-off voltage and a predetermined drain voltage is larger than a second drain conductance of the second field effect transistor when applying both a gate voltage and the predetermined drain voltage, such that when measuring the first drain conductance, a drain current having a same value as a drain current flowing through the first field effect transistor flows through the second field effect transistor.

### CROSS REFERENCE TO RELATED APPLICATIONS

This application claims priority based on Japanese Patent Application No. 2024-150900 filed on Sep. 2, 2024, and the entire contents of the Japanese Patent Application are incorporated herein by reference.

### TECHNICAL FIELD

The present disclosure relates to a semiconductor device and a Doherty amplifier.

### BACKGROUND

A Doherty amplifier is known as an amplifier for amplifying a high-frequency signal such as a microwave. In the Doherty amplifier, a main amplifier and a peak amplifier amplify input signals in parallel, and the amplified signals are combined by a combiner.
Patent literature 1: WO 2005/119787

### SUMMARY

A semiconductor device for a Doherty amplifier according to an embodiment of the present disclosure includes a main amplifier including a first field effect transistor having a first nitride semiconductor layer, a first source electrode, a first gate electrode, and a first drain electrode, the first source electrode, the first gate electrode, and the first drain electrode being provided on the first nitride semiconductor layer, the main amplifier being configured to amplify a first signal distributed from an input signal, and a peak amplifier including a second field effect transistor including a second nitride semiconductor layer, a second source electrode, a second gate electrode, and a second drain electrode, the second source electrode, the second gate electrode, and the second drain electrode being provided on the second nitride semiconductor layer, the peak amplifier being configured to amplify a second signal distributed from the input signal. A first drain conductance of the first field effect transistor when a gate voltage obtained by adding a predetermined voltage to a pinch-off voltage and a predetermined drain voltage are applied is larger than a second drain conductance of the second field effect transistor when a gate voltage and the predetermined drain voltage are applied such that a drain current having a same value as a value of a drain current flowing through the first field effect transistor in a measurement of the first drain conductance flows through the second field effect transistor.

### BRIEF DESCRIPTION OF THE DRAWINGS

FIG. 1 is a block diagram of a Doherty amplifier according to a first embodiment.

FIG. 2 is a diagram showing the drain characteristics of a field effect transistor 11.

FIG. 3 is a diagram showing the drain characteristics of a field effect transistor 13.

FIG. 4 is a diagram showing gain and the drain efficiency DE with respect to output power Pout of the Doherty amplifier.

FIG. 5 is a diagram showing impedances Zm and Zp with respect to output power Pout of the Doherty amplifier.

FIG. 6 is a schematic diagram showing the drain current with respect to time in a main amplifier.

FIG. 7 is a schematic diagram showing the gain with respect to the input power Pin in the main amplifier.

FIG. 8 is a diagram showing distortion with respect to an off-leakage current.

FIG. 9 is a schematic diagram showing the drain lag with respect to drain conductance.

FIG. 10 is a cross-sectional view showing a structural example 1 of the field effect transistor 11.

FIG. 11 is a cross-sectional view showing a structural example 1 of the field effect transistor 13.

FIG. 12 is a cross-sectional view showing a structural example 2 of the field effect transistor 13.

FIG. 13 is a cross-sectional view showing a structural example 3 of the field effect transistor 13.

FIG. 14 is a cross-sectional view showing a structural example 4 of the field effect transistor 13.

FIG. 15 is a cross-sectional view showing a structural example 5 of the field effect transistor 13.

FIG. 16 is a cross-sectional view showing a structural example 6 of the field effect transistor 13.

FIG. 17 is a cross-sectional view showing a structural example 7 of the field effect transistor 13.

FIG. 18 is a cross-sectional view showing a structural example 8 of the field effect transistor 13.

FIG. 19 is a cross-sectional view showing a structural example 2 of the field effect transistor 11.

FIG. 20 is a cross-sectional view showing a structural example 9 of the field effect transistor 13.

FIG. 21 is a cross-sectional view showing example 10 of the field effect a structural transistor 13.

FIG. 22 is a plan view showing an example 1 of a semiconductor device used in the first embodiment.

FIG. 23 is a plan view showing an example 2 of the semiconductor device used in the first embodiment.

### DETAILED DESCRIPTION

In the Doherty amplifier, it is required to improve efficiency and reduce distortion.

An object of the present disclosure is to provide a semiconductor device and a Doherty amplifier with improved characteristics.

### Description of Embodiments of Present Disclosure

First, embodiments of the present disclosure will be listed and described.
(1) A semiconductor device for a Doherty amplifier according to an embodiment of the present disclosure includes a main amplifier including a first field effect transistor having a first nitride semiconductor layer, a first source electrode, a first gate electrode, and a first drain electrode, the first source electrode, the first gate electrode, and the first drain electrode being provided on the first nitride semiconductor layer, the main amplifier being configured to amplify a first signal distributed from an input signal, and a peak amplifier including a second field effect transistor including a second nitride semiconductor layer, a second source electrode, a second gate electrode, and a second drain electrode, the second source electrode, the second gate electrode, and the second drain electrode being provided on the second nitride semiconductor layer, and the peak amplifier being configured to amplify a second signal distributed from the input signal. A first drain conductance of the first field effect transistor when applying a gate voltage obtained by adding a predetermined voltage to a pinch-off voltage and a predetermined drain voltage are applied is larger than a second drain conductance of the second field effect transistor when applying a gate voltage and the predetermined drain voltage, such that when measuring the first drain conductance, a drain current having a same value as a drain current flowing through the first field effect transistor flows through the second field effect transistor. This allows for a balance between efficiency and distortion, leading to improved characteristics.
(2) In the above (1), the first nitride semiconductor layer may include a first buffer layer provided over a first substrate and a first electron supply layer provided on the first buffer layer, the second nitride semiconductor layer may include a second buffer layer provided over a second substrate and a second electron supply layer provided on the second buffer layer, and the first buffer layer may be thicker than the second buffer layer. This makes it possible to make the drain conductance of the first field effect transistor larger than the drain conductance of the second field effect transistor.
(3) In the above (1) or (2), the first nitride semiconductor layer may include a first aluminum nitride layer provided on a first substrate, a first gallium nitride buffer layer provided on the first aluminum nitride layer, and a first electron supply layer provided on the first gallium nitride buffer layer, the second nitride semiconductor layer may include a second aluminum nitride layer provided on a second substrate, a second gallium nitride buffer layer provided on the second aluminum nitride layer, and a second electron supply layer provided on the second gallium nitride buffer layer, and the first aluminum nitride layer may be thinner than the second aluminum nitride layer. This makes it possible to make the drain conductance of the first field effect transistor larger than the drain conductance of the second field effect transistor.
(4) In any one of the above (1) to (3), the first nitride semiconductor layer may include a first buffer layer provided over a first substrate and a first electron supply layer provided on the first buffer layer, the second nitride semiconductor layer may include a second buffer layer provided over a second substrate and a second electron supply layer provided on the second buffer layer, and a distance between the first buffer layer and the first gate electrode in a thickness direction of the first nitride semiconductor layer may be larger than a distance between the second buffer layer and the second gate electrode in a thickness direction of the second nitride semiconductor layer. This makes it possible to make the drain conductance of the first field effect transistor larger than the drain conductance of the second field effect transistor.
(5) In any one of the above (1) to (4), the first nitride semiconductor layer may include a first buffer layer provided over a first substrate and a first electron supply layer provided on the first buffer layer, the second nitride semiconductor layer may include a second buffer layer provided over a second substrate and a second electron supply layer provided on the second buffer layer, and a carbon concentration of the first buffer layer may be lower than a carbon concentration of the second buffer layer. This makes it possible to make the drain conductance of the first field effect transistor larger than the drain conductance of the second field effect transistor.
(6) In any one of the above (1) to (5), a gate length of the first gate electrode may be shorter than a gate length of the second gate electrode. This makes it possible to make the drain conductance of the first field effect transistor larger than the drain conductance of the second field effect transistor.
(7) In any one of the above (1) to (6), the first gate electrode may overhang at least toward the first drain electrode, the second gate electrode may overhang t toward the second drain electrode, and a length of the first gate electrode overhanging toward the first drain electrode may be shorter than a length of the second gate electrode overhanging toward the second drain electrode. This makes it possible to make the drain conductance of the first field effect transistor larger than the drain conductance of the second field effect transistor.
(8) In any one of the above (1) to (7), the first field effect transistor may include a first field plate provided above the first nitride semiconductor layer the between first gate electrode and the first drain electrode, the second field effect transistor may include a second field plate provided above the second nitride semiconductor layer between the second gate electrode and the second drain electrode, and a distance between the first nitride semiconductor layer and the first field plate in a thickness direction of the first nitride semiconductor layer may be larger than a distance between the second nitride semiconductor layer and the second field plate in a thickness direction of the second nitride semiconductor layer. This makes it possible to make the drain conductance of the first field effect transistor larger than the drain conductance of the second field effect transistor.
(9) In any one of the above (1) to (8), the first field effect transistor may include a first field plate provided above the first nitride semiconductor layer between the first gate electrode and the first drain electrode, the second field effect transistor may include a second field plate provided above second nitride the semiconductor layer between the second gate electrode and the second drain electrode, and a distance between an end of the first gate electrode close to the first drain electrode and an end of the first field plate close to the first drain electrode may be smaller than a distance between an end of the second gate electrode close to the second drain electrode and an end of the second field plate close to the second drain electrode. This makes it possible to make the drain conductance of the first field effect transistor larger than the drain conductance of the second field effect transistor.
(10) A Doherty amplifier may include the semiconductor device according to any one of (1) to (9), a divider configured to divide the input signal into the first signal and the second signal, and a combiner configured to combine the first signal amplified by the main amplifier and the second signal amplified by the peak amplifier. This allows for a balance between efficiency and distortion, leading to improved characteristics.

### Details of Embodiments of Present Disclosure

Specific examples of a semiconductor device and a Doherty amplifier according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

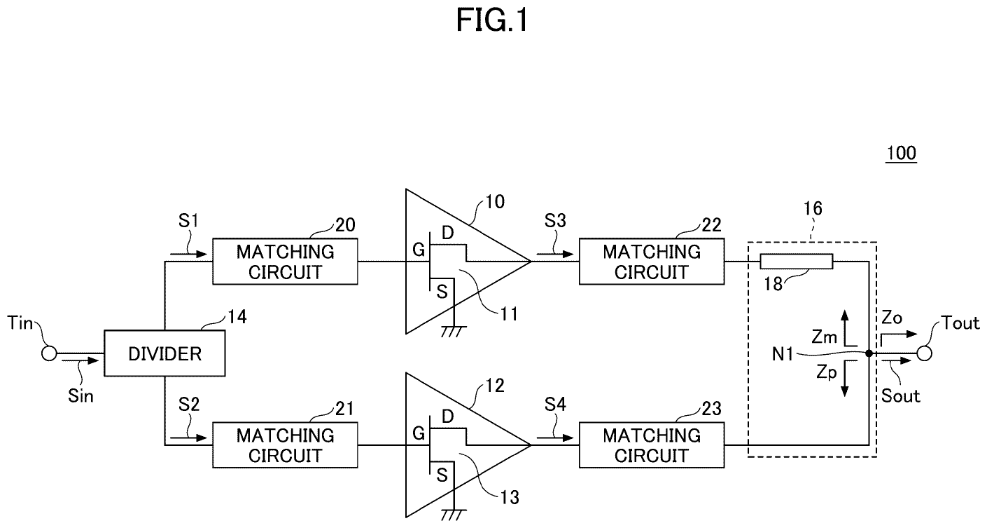

FIG. 1 is a block diagram of a Doherty amplifier according to a first embodiment. As shown in FIG. 1, in a Doherty amplifier 100, a main amplifier 10 and a peak amplifier 12 are connected in parallel between an input terminal Tin and an output terminal Tout. A high-frequency signal is input to the input terminal Tin as an input signal Sin. A divider 14 divides the input signal Sin into two signals S1 (first signal) and S2 (second signal). When the Doherty amplifier 100 is used in power amplifiers of base stations of mobile communication, the frequencies of the input signal Sin are, for example, 0.5 GHz to 20 GHZ.

The signal S1 is input to the main amplifier 10 via a matching circuit 20. The matching circuit 20 matches the impedance of the matching circuit 20 as viewed from the divider 14 with the impedance of the main amplifier 10 as viewed from the matching circuit 20. The main amplifier 10 amplifies the input signal S1 and outputs an amplified signal S3 (third signal). The signal S3 is input to a combiner 16 via a matching circuit 22. The matching circuit 22 matches the impedance of the matching circuit 22 as viewed from the main amplifier 10 with the impedance of the combiner 16 as viewed from the matching circuit 22.

A signal S2 is input to the peak amplifier 12 via a matching circuit 21. The matching circuit 21 matches the impedance of the matching circuit 21 as viewed from the divider 14 with the impedance of the peak amplifier 12 as viewed from the matching circuit 21. The peak amplifier 12 amplifies the input signal S2 and outputs an amplified signal S4 (fourth signal). The signal S4 is input to the combiner 16 via a matching circuit 23. The matching circuit 23 matches the impedance of the matching circuit 23 as viewed from the peak amplifier 12 with the impedance of the combiner 16 as viewed from the matching circuit 23. The combiner 16 includes an impedance converter 18. The signal S3 input to the combiner 16 is combined with the signal S4 at a node N1 via the impedance converter 18. The combined signals S3 and S4 are output to the output terminal Tout as the output signal Sout.

The main amplifier 10 and the peak amplifier 12 include field effect transistors (FETs) 11 (first field effect transistor) and 13 (second field effect transistor), respectively. The field effect transistors 11 and 13 are provided in the nitride semiconductor layer, and are, for example, GaN (gallium nitride) HEMTs (High Electron Mobility Transistors). In the field effect transistors 11 and 13, the sources S are grounded, the signals S1 and S2 are input to the gates G, respectively, and the signals $3 and S4 are output from the drains D, respectively.

The main amplifier 10 operates in class AB or class B, and the peak amplifier 12 operates in class C. Thus, when the input power of the input signal Sin is small, the main amplifier 10 mainly amplifies the input signal Sin. When the input power gradually becomes large, the peak amplifier 12 amplifies the input signal Sin in addition to the main amplifier 10. The output power of the output signal Sout just before the peak amplifier 12 starts operating is referred to as backoff power Pbo. As the input power becomes even larger, the output power when both the main amplifier 10 and the peak amplifier 12 are in saturation power is referred to as the saturation power Psat.

The matching circuit 22 is designed to increase the efficiency of the main amplifier 10 when the backoff power Pbo is applied, and to improve the output power of the main amplifier 10 when the saturation power Psat is applied. The matching circuit 23 is designed to improve the output power of the peak amplifier 12 when the saturation power Psat is applied. The impedance of the output terminal Tout as viewed from the node N1 is represented by Zo. Zo is approximately real. The impedance converter 18 is designed such that the impedance Zm viewed from the node N1 via the impedance converter 18 to the main amplifier 10 is Zo at the backoff power Pbo, and the impedance Zm becomes 2×Zo at the saturation power Psat. The matching circuit 23 is designed such that an impedance Zp viewed from the node N1 to the peak amplifier 12 is approximately infinite at the backoff power Pbo, and the impedance Zp becomes 2×Zo at the saturation power Psat. The impedances Zm and Zp2×Zo are obtained when the Doherty amplifier 100 is a symmetrical Doherty amplifier (that is, when the main amplifier 10 and the peak amplifier 12 have the same size). When the Doherty amplifier 100 is an asymmetric Doherty amplifier, the impedances Zm and Zp are appropriately designed in the saturation power Psat.

### (Description of Drain Conductance of Field Effect Transistors 11 and 13)

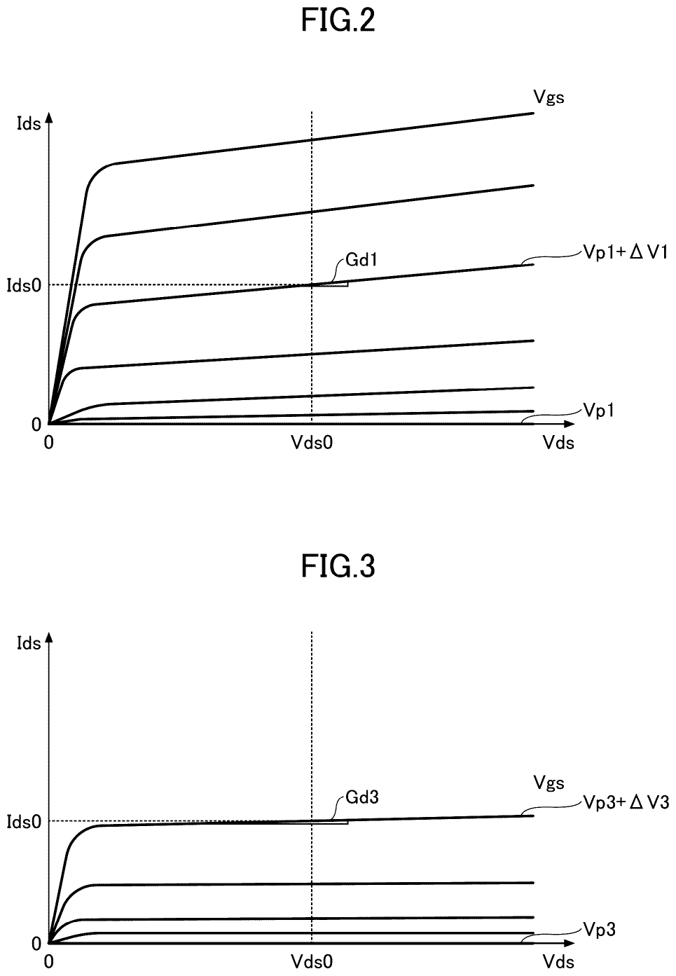

FIG. 2 and FIG. 3 are diagrams showing the drain characteristics of the field effect transistors 11 and 13, respectively. In FIG. 2 and FIG. 3, the horizontal axis represents the drain voltage Vds, and the vertical axis represents the drain current Ids. Vds0 is a drain bias voltage applied to the field effect transistors 11 and 13 during operation. The pinch-off voltages of the field effect transistors 11 and 13 are Vp1 and Vp3, respectively. The gate voltage Vgs is applied in a constant voltage step with reference to the pinch-off voltages Vp1 and Vp3. A gate bias voltage Vgs1 of the field effect transistor 11 is Vp1+ΔV1. A gate bias voltage Vgs3 of the field effect transistor 13 is larger in negative than the pinch-off voltage Vp3. That is, when the gate voltage Vgs of the field effect transistor 13 is Vgs3, the field effect transistor 13 is pinched off. A drain conductance Gd corresponds to the gradient of the drain current Ids with respect to the drain voltage Vds. For example, in the field effect transistor 11, a drain conductance Gd1 when the drain voltage Vds is Vds0 and the gate voltage Vgs is Vp1+ΔV1 is set as the drain conductance. In the field effect transistor 13, a drain conductance Gd3 when the drain voltage Vds is Vds0 and the gate voltage Vgs is Vp3+ΔV3 is defined as the drain conductance. Here, ΔV3 in the field effect transistor 13 is a value set so that a drain current Ids0 in the field effect transistor 13 has the same value as the drain current Ids0 when the gate voltage of the field effect transistor 11 is Vp1+ΔV1. The drain conductance Gd3 of the field effect transistor 13 is smaller than the drain conductance Gd1 of the field effect transistor 11.

### (Reason for Reducing Drain Conductance Gd3 of Field Effect Transistor 13)

The reason why the drain conductance Gd3 of the field effect transistor 13 is made smaller than the drain conductance Gd1 of the field effect transistor 11 in the first embodiment will be described. First, in a Doherty amplifier, a simulation was performed for a case where the drain conductance of the field effect transistor 13 of the peak amplifier 12 was changed. In the simulation, it was assumed that changing the gate bias voltage Vgs3 of the field effect transistor 13 corresponds to changing the drain conductance Gd3. That is, when the gate bias voltage Vgs3 is reduced to a small negative value, it results in a softer pinch-off, which is considered to correspond to a condition of high drain conductance. In the simulation, the reactance components of the field effect transistors 11 and 13 are not considered. Thus, although the values of the numerical values are not accurate, the tendency of the numerical values can be simulated.

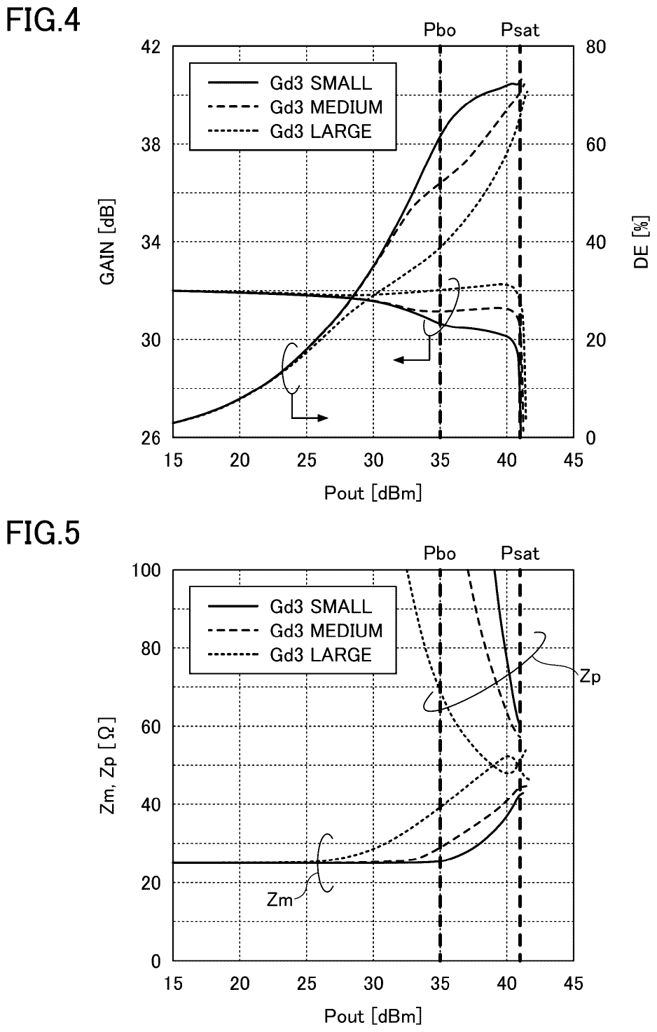

FIG. 4 is a diagram showing gain and the drain efficiency DE with respect to output power Pout of the Doherty amplifier. The horizontal axis represents the output power Pout of the output signal Sout, and the vertical axis represents the linear gain and the drain efficiency DE. FIG. 5 is a diagram showing impedances Zm and Zp with respect to output power Pout of the Doherty amplifier. The horizontal axis represents the output power Pout, and the vertical axis represents the impedance Zm of the main amplifier 10 as viewed from the node N1 and the impedance Zp of the peak amplifier 12 as viewed from the node N1. Since the reactance component is not considered, the impedances Zm and Zp are real. An impedance Zo is assumed to be 25Ω. The solid line, the dashed line, and the dotted line correspond to the cases where the drain conductance Gd3 is small, medium, and large, respectively. When the output power is 35 dBm and 41 dBm, the output power corresponds to the backoff power Pbo and the saturation power Psat, respectively.

As shown in FIG. 4, at the saturation power Psat, the drain efficiency DE is substantially the same value regardless of the drain conductance Gd3. At the backoff power Pbo, the drain efficiency DE decreases as the drain conductance Gd3 increases.

As shown in FIG. 5, when the drain conductance Gd3 is small, the impedances Zm and Zp are approximately 50Ω at the saturation power Psat, and the impedances Zm and Zp are approximately 25Ω and approximately infinity at the backoff power Pbo, respectively. Thus, the impedances Zm and Zp are substantially the designed values. When the drain conductance Gd3 is large, the impedances Zm and Zp are approximately 50Ω at the saturation power Psat. However, at the backoff power Pbo, the impedance Zp becomes smaller than infinity, and the impedance Zm becomes larger than 25Ω. When the drain conductance Gd3 is large, the field effect transistor 13 tends to be on even at low input power, and the field effect transistor 13 is not turned off at the backoff power Pbo. Thus, the impedance Zp becomes smaller than infinity. Further, the impedance Zm becomes larger than 25Ω. As a result, the matching condition of the load impedance of the main amplifier 10 at the backoff power Pbo deviates from the condition for improving the efficiency. Thus, as shown in FIG. 4, the drain efficiency DE near the backoff power Pbo is reduced. As described above, the efficiency can be improved by reducing the drain conductance Gd3 of the peak amplifier 12.

### (Description of Drain Lag)

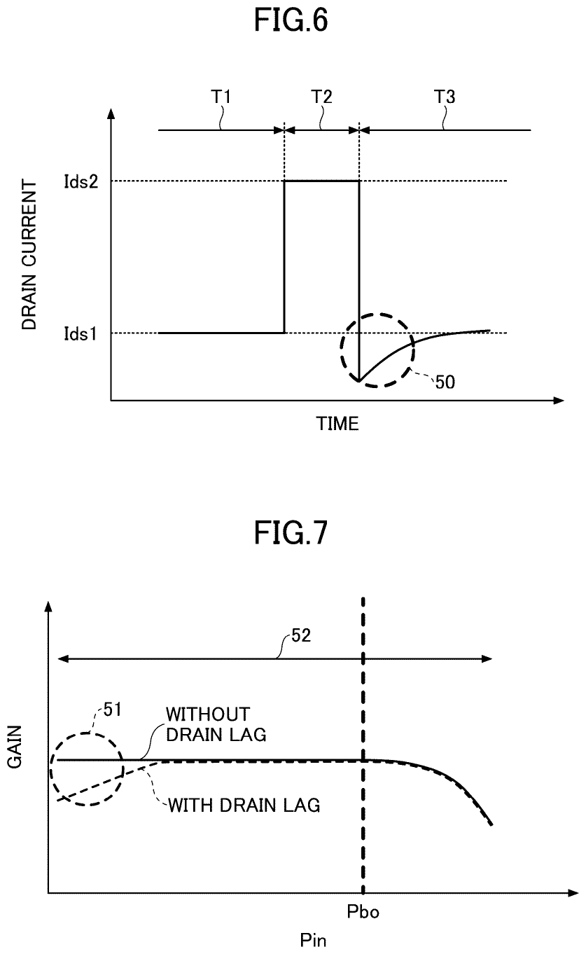

The drain lag in the field effect transistor using the nitride semiconductor layer will be described. FIG. 6 is a schematic diagram showing the drain current with respect to in a main amplifier. Periods T1 and T3 on the horizontal axis are periods in which the input power is small and the main amplifier 10 does not amplify the input signal Sin, and a period T2 is a period in which the input power is large and the main amplifier 10 amplifies the input signal Sin. The drain current on the vertical axis is the drain bias current in the periods T1 to T3. As shown in FIG. 6, in the first period T1, the drain current is Ids1. In the period T2, the drain current increases to Ids2. Just after the transition from period T2 to period T3, as shown by a broken line circle 50, the drain current decreases below the Ids1, and then the drain current increases with time to reach the Ids1.

FIG. 7 is a schematic diagram showing the gain with respect to the input power Pin in the main amplifier. The solid line indicates the case where there is no drain lag, and the dashed line indicates the case where there is a drain lag. Pbo on the horizontal axis represents the input power Pin corresponding to the backoff power. As shown in FIG. 7, in the case where there is no drain lag, the gain is substantially constant when the input power Pin is equal to or less than Pbo, and the gain decreases when the input power Pin exceeds Pbo. As indicated by an arrow 52, even when the input power Pin changes with time, the gain characteristic with respect to the input power Pin does not change when the input power Pin is equal to or less than Pbo.

In the case where there is a drain lag, the state in which the input power Pin decreases as indicated by the leftward arrow 52 corresponds to the state just after the period T2 has shifted to the period T3 in FIG. 6. Thus, the drain current decreases, and the gain decreases. Thus, the gain is reduced as in a broken line circle 51. Thus, since the gain is not constant at the input power Pin equal to or less than Pbo, Amplitude Modulation (AM)−AM distortion increases.

(Relationship between Drain Lag and Drain Conductance)

In order to examine the relationship between the drain lag and the drain conductance, the correlation between the off-leakage current in the GaN HEMT and the distortion characteristics of the Doherty amplifier was examined. The distortion characteristics of the Doherty amplifier are distortion characteristics of a Doherty amplifier manufactured using the same wafer as the wafer used for measuring the pinch-off characteristics.

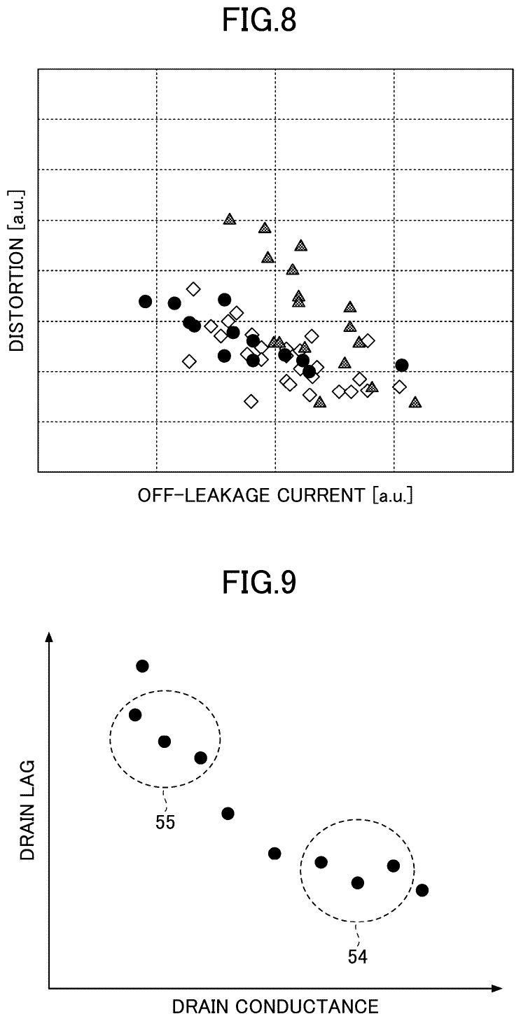

FIG. 8 is a diagram showing distortion with respect to an off-leakage current. The off-leakage current of the horizontal axis is a current that mainly flows through the buffer layer when the field effect transistor is completely pinched off. The distortion on the vertical axis indicates the distortion of the modulated wave of the Doherty amplifier, and indicates that the distortion characteristic is deteriorated as the distortion increases. Each dot indicates a measurement point, and the structure of the GaN HEMT is the same for the same type of dot (circle, triangle, and square). The structure of the GaN HEMT is different for different types of dots. The variation in the same dot is caused by manufacturing variation or the like. As shown in FIG. 8, the distortion is improved when the off-leakage current is large, and the distortion is deteriorated when the off-leakage current is small. A large off-leakage current indicates that the pinch-off characteristic of the field effect transistor is bad, and corresponds to a large drain conductance. As described in FIG. 7, it is considered that the bad distortion corresponds to the large drain lag.

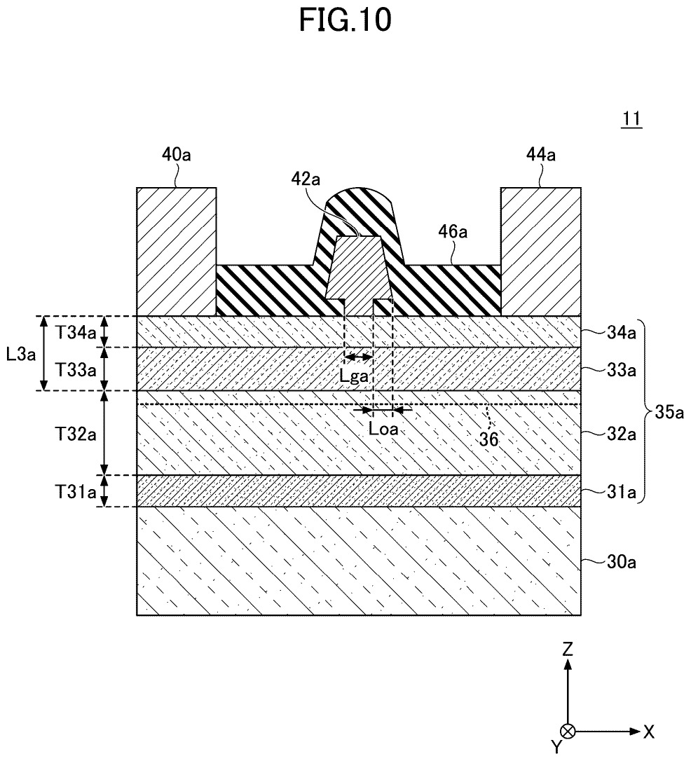

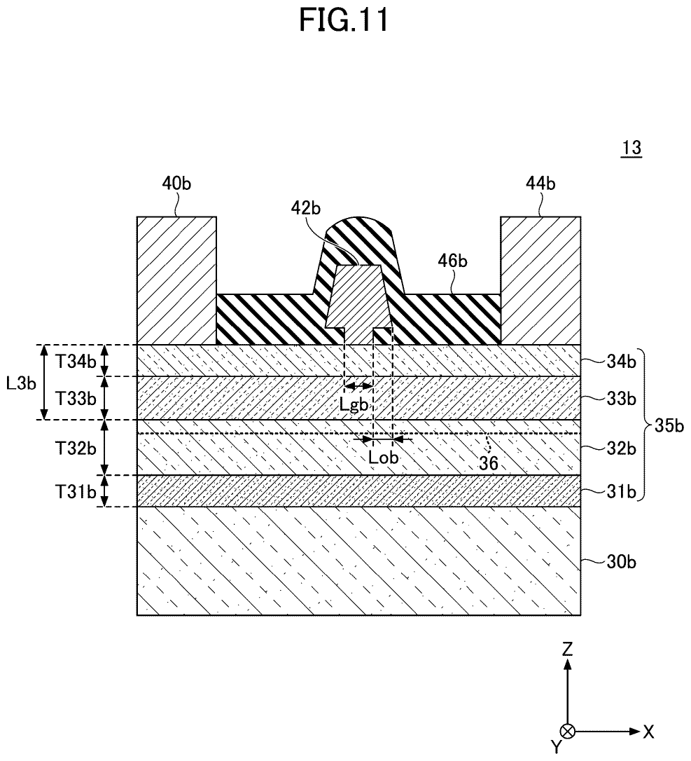

FIG. 9 is a schematic diagram showing drain lag with respect to drain conductance. The drain lag on the vertical axis shows that the drop of the drain current in the broken line circle 50 of FIG. 6 is large when the drain lag is large. The dots indicate the drain lag with respect to the drain conductance of several types of GaN HEMTs. As shown in FIG. 9, the drain lag decreases as the drain conductance increases. When the drain conductance is reduced, the drain lag is increased.

### (Comparison of Comparative Object and First Embodiment)

Table 1 shows the drain conductance, efficiency, distortion, field effect transistor and design policy for amplifiers A to D.

TABLE 1

| | DRAIN CONDUCTANCE | | | | | |
|---|---|---|---|---|---|---|
| | MAIN | PEAK | | | | DESIGN |
| AMPLIFIER | AMPLIFIER | AMPLIFIER | EFFICIENCY | DISTORTION | FET | POLICY |
| A | LARGE | LARGE | BAD | GOOD | SAME | DISTORTION |
| | | | | | | PRIORITY |
| B | SMALL | SMALL | GOOD | BAD | SAME | EFFICIENCY |
| | | | | | | PRIORITY |
| C | LARGE | SMALL | GOOD | GOOD | SAME | DIFFICULT |
| D | LARGE | SMALL | GOOD | GOOD | DIFFERENT | BOTH |
| | | | | | | DISTORTION |
| | | | | | | AND EFFICIENCY |

The amplifiers A and B correspond to the comparison targets, and the amplifiers C and D correspond to the first embodiment. The drain conductance indicates whether the drain conductance in the main amplifier 10 and the peak amplifier 12 is large or small. The efficiency indicates that the drain efficiency of the Doherty amplifier at the backoff power Pbo is bad or good. The distortion indicates that the modulation wave distortion is bad or good. The field effect transistor indicates that the field effect transistor 11 and the field effect transistor 13 have the same structure or different structures.

As shown in Table 1, in the amplifier A, the drain conductance is large in both the main amplifier 10 and the peak amplifier 12. Thus, the drain efficiency at the backoff power Pbo is deteriorated. The distortion of the modulation wave is improved. The structures of the field effect transistors 11 and 13 can be the same. The amplifier A is designed to emphasize distortion over efficiency.

In an amplifier B, the drain conductance of both the main amplifier 10 and the peak amplifier 12 is small. Thus, the drain efficiency at the backoff power Pbo is improved. The distortion of the modulation wave is deteriorated. The field effect transistors 11 and 13 can have the same structure. The amplifier B is designed to emphasize efficiency over distortion. In a field effect transistor other than the field effect transistor having the nitride semiconductor layer, the drain lag is small, and thus, by adopting the amplifier B, a balance between efficiency and distortion becomes possible.

In the amplifier C, the drain conductance of the main amplifier 10 is made large as shown by a broken line circle 54 in FIG. 9, while the drain conductance of the peak amplifier 12 is made small as shown by a broken line circle 55. When the drain conductance of the peak amplifier 12 is reduced, the drain efficiency DE at the backoff power Pbo can be increased. Even when the drain conductance of the main amplifier 10 is large, the efficiency of the backoff power Pbo is hardly affected. Thus, the efficiency at the backoff power Pbo is improved. When the drain conductance of the main amplifier 10 is increased, the drain lag of the main amplifier 10 is reduced. Thus, the distortion of the modulated wave is reduced. When the drain conductance of the peak amplifier 12 is small, the drain lag of the peak amplifier 12 is large. However, since the input signal Sin is primarily amplified by the main amplifier 10, the drain lag of the peak amplifier 12 has little effect on the modulation distortion, even when it is large. When the field effect transistors 11 and 13 have the same structure, the amplifier C is difficult to construct.

An amplifier D has the same drain conductance, efficiency and distortion as the amplifier C. The difference from the amplifier C is that the structures of the field effect transistors 11 and 13 are different. This facilitates implementation. In the amplifier D, a balance between efficiency and distortion becomes possible, resulting in improved performance characteristics.

In the Doherty amplifier 100 of the first embodiment, as shown in FIG. 2 and FIG. 3, the drain conductance Gd1 (first drain conductance) of the field effect transistor 11 when the gate voltage Vgs obtained by adding the certain voltage ΔV1 (positive value) to the pinch-off voltage Vp1 and the constant drain voltage Vds are applied is larger than the drain conductance Gd3 (second drain conductance) of the field effect transistor 13 when the gate voltage Vgs and the certain drain voltage Vds are applied such that the drain current Ids0 having the same value as the drain current Ids0 flowing through the field effect transistor 11 flows in a measurement of the drain conductance Gd1 flows through the field effect transistor 13. Here, the certain drain voltage applied to the field effect transistor 11 and the certain drain voltage applied to the field effect transistor 13 have the same error range. Both the drain current Ids0 flowing through the field effect transistor 11 when measuring the drain conductance Gd1 and the drain current Ids0 flowing through the field effect transistor 13 when measuring the drain conductance Gd3 have the same error range. It is noted that, the drain current is a drain current per unit gate width. This allows for a balance between efficiency and distortion, as shown in Table 1, leading to improved performance characteristics.

When the gate widths of the field effect transistors 11 and 13 are different, Gd1 and Gd3 are compared using a value [S/mm] normalized by the gate width. The method for measuring the drain conductances Gd1 and Gd3 is as follows. Using a network analyzer, a predetermined gate voltage Vgs and a predetermined drain voltage Vds are applied to measure S parameters. The drain conductance (reciprocal of the drain resistance) extracted from the measured S parameter using an equivalent circuit of a field effect transistor can be used.

An example of setting the gate voltage Vgs and the drain voltage Vds will be described. For example, ΔV1 is set so that Vp1+ΔV1 is the operating point of the main amplifier 10. The drain voltages Vds of the field effect transistors 11 and 13 are set to the same voltage, for example, a drain bias voltage Vds0 applied to the field effect transistors 11 and 13 when the Doherty amplifier 100 operates. The pinch-off voltages Vp1 and Vp3 are defined as gate voltages Vgs at which the drain current [A/mm] in a unit gate width becomes a predetermined value in a state where the drain bias voltage Vds0 is applied as the drain voltage Vds of the field effect transistors 11 and 13.

The drain conductance Gd1 is, for example, 1.1 times or more, 1.2 times or more, or twice or more as large as Gd3. When the drain conductance Gd1 is too large, the high frequency characteristics are deteriorated. From this viewpoint, the drain conductance Gd1 is, for example, 10 times or less as large as Gd3. When Vds is 50 V and the drain current Ids0 in the unit gate width is 10 mA/mm, the drain conductance Gd1 is, for example, 0.1 mS/mm to 10 mS/mm, for example, 1 mS/mm, and the drain conductance Gd3 is, for example, 0.1 mS/mm to 10 mS/mm, for example, 0.5 mS/mm.

### (Structural Example 1 of the Field Effect Transistor 11)

FIG. 10 is a cross-sectional view showing structural example 1 of the field effect transistor 11. The direction from a source electrode 40a to a drain electrode 44a is referred to as X direction, the thickness direction of a nitride semiconductor layer 35a is referred to as Z direction, and the direction orthogonal to the X direction and the Z direction is referred to as Y direction. As shown in FIG. 10, in the field effect transistor 11, the nitride semiconductor layer 35a (first nitride semiconductor layer) is provided on a substrate 30a (first substrate). The nitride semiconductor layer 35a includes a nucleation layer 31a (first aluminum nitride layer) provided on the substrate 30a, a buffer layer 32a (first buffer layer or first gallium nitride buffer layer) provided on the nucleation layer 31a, an electron supply layer 33a (first electron supply layer) provided on the buffer layer 32a, and a cap layer 34a provided on the electron supply layer 33a. The source electrode 40a (first source electrode) and the drain electrode 44a (first drain electrode) are provided on the nitride semiconductor layer 35a. A gate electrode 42a (first gate electrode) is provided between the source electrode 40a and the drain electrode 44a on the nitride semiconductor layer 35a. An insulating layer 46a is provided on the nitride semiconductor layer 35a so as to cover the gate electrode 42a.

### (Structural Example 1 of Field Effect Transistor 13)

FIG. 11 is a cross-sectional view showing the structural example 1 of the field effect transistor 13. As shown in FIG. 11, a nitride semiconductor layer 35b (second nitride semiconductor layer) is provided on a substrate 30b (second substrate). The nitride semiconductor layer 35b includes a nucleation layer 31b (second aluminum nitride layer), a buffer layer 32b (second buffer layer or second gallium nitride buffer layer), an electron supply layer 33b (second electron supply layer), and a cap layer 34b. A source electrode 40b (second source electrode), a gate electrode 42b (second gate electrode), a drain electrode 44b (second drain electrode), and an insulating layer 46b are provided on the nitride semiconductor layer 35b. In the field effect transistor 13, a thickness T32b of the buffer layer 32b is smaller than the thickness T32a of the buffer layer 32a in the field effect transistor 11. The thickness, size, material, and the like of each of the other layers are the same as those of the field effect transistor 11 shown in FIG. 10. Here, same thicknesses, sizes, and materials do not necessarily mean strictly identical, and allows for differences within manufacturing tolerances. The same applies to the following structural examples.

The substrates 30a and 30b are semiconductor substrates or insulating substrates, for example, silicon carbide (Sic) substrates, sapphire substrates, or gallium nitride (GaN) substrates. The nucleation layers 31a and 31b are, for example, aluminum nitride (AlN) layers, and are layers for generating nuclei when the buffer layers 32a and 32b are formed. The buffer layers 32a and 32b are, for example, gallium nitride (GaN) layers. The electron supply layers 33a and 33b are, for example, aluminum gallium nitride (AlGaN) layers. The band gap energy of the electron supply layers 33a and 33b is larger than the band gap energy of the buffer layers 32a and 32b. A two dimensional electron gas 36 is formed in the buffer layers 32a and 32b in the near the electron supply layers 33a and 33b. The two dimensional electron gas 36 functions as a channel. The cap layers 34a and 34b are, for example, gallium nitride layers, and function as protective layers for the electron supply layers 33a and 33b.

At least one of the nucleation layers 31a and 31b and the cap layers 34a and 34b may not be provided. It is sufficient that the nucleation layers 31a and 31b, the buffer layers 32a and 32b, the electron supply layers 33a and 33b, and the cap layers 34a and 34b are each made of a nitride semiconductor layer. The nucleation layers 31a and 31b are made of the same material, for example. The buffer layers 32a and 32b are made of the same material, for example. The electron supply layers 33a and 33b are made of the same material, for example. The cap layers 34a and 34b are made of the same material, for example.

The nucleation layer 31a, the buffer layer 32a, the electron supply layer 33a, and the cap layer 34a have thicknesses T31a, T32a, T33a, and T34a, respectively. The distance between the buffer layer 32a and the gate electrode 42a in the thickness direction of the nitride semiconductor layer 35a is L3a. The nucleation layer 31b, the buffer layer 32b, the electron supply layer 33b, and the cap layer 34b have thicknesses T31b, T32b, T33b, and T34b, respectively. The distance between the buffer layer 32b and the gate electrode 42b in the thickness direction of the nitride semiconductor layer 35b is L3b.

The source electrodes 40a and 40b and the drain electrodes 44a and 44b are metal layers, and each of these electrodes includes, for example, a titanium film and an aluminum film in order from the side closer to the nitride semiconductor layers 35a and 35b. The gate electrodes 42a and 42b are metal layers, and each of these electrodes includes, for example, a nickel film and a gold film in order from the side closer to the nitride semiconductor layers 35a and 35b. The insulating layers 46a and 46b are inorganic insulator layers such as silicon nitride layers. The lengths of the gate electrodes 42a and 42b in the X direction in contact with the nitride semiconductor layers 35a and 35b are gate lengths Lga and Lgb, respectively. The cross-sectional shape of the gate electrodes 42a and 42b in the XY plane is an overhang structure. That is, the gate electrodes 42a and 42b have first portions in contact with the nitride semiconductor layers 35a and 35b, and second portions on the first portions and having a width in the X direction larger than that of the first portions. The overhang lengths Loa and Lob of the gate electrodes 42a and 42b overhanging the drain electrodes 44a and 44b are distances in the X direction between positions closest to the drain electrodes 44a and 44b in regions where the gate electrodes 42a and 42b are in contact with the nitride semiconductor layers 35a and 35b and positions closest to the drain electrodes 44a and 44b in the gate electrodes 42a and 42b.

The thicknesses T31a and T31b are, for example, 5 nm to 50 nm, and are 15 nm as an example. The thicknesses T32a and T32b are, for example, 50 nm to 1000 nm, and are 500 nm as an example. The thicknesses T33a and T33b are, for example, 5 nm to 30 nm, and are 20 nm as an example. The thicknesses T34a and T34b are, for example, 1 nm to 10 nm, and are 5 nm as an example. The distances L3a and L3b are, for example, 6 nm to 40 nm, and are 25 nm as an example. The gate lengths Lga and Lgb are, for example, 0.1 μm to 1.0 μm, and are 0.5 μm as an example. The overhang lengths Loa and Lob are, for example, 0.05 μm to 0.50 μm, and are 0.20 μm as an example.

As shown in FIG. 10 and FIG. 11, the buffer layer 32a is thicker than the buffer layer 32b. Thus, the energy at the bottom of the conduction band in the buffer layer 32a near the two dimensional electron gas 36 in the field effect transistor 11 is lower than the energy at the bottom of the conduction band in the buffer layer 32b near the two dimensional electron gas 36 in the field effect transistor 13. Thus, the drain conductance Gd1 of the field effect transistor 11 can be made larger than Gd3.

The thickness T32a is, for example, equal to or more than 1.05 times, equal to or more than 1.1 times, and equal to or more than 1.2 times a thickness T32b. When the thickness T32a is too large, the drain conductance Gd1 of the field effect transistor 11 becomes too large, and the high frequency characteristics deteriorate. From this viewpoint, the thickness T32a can be equal to or less than twice the thickness T32b.

### (Structural Example 2 of Field Effect Transistor 13)

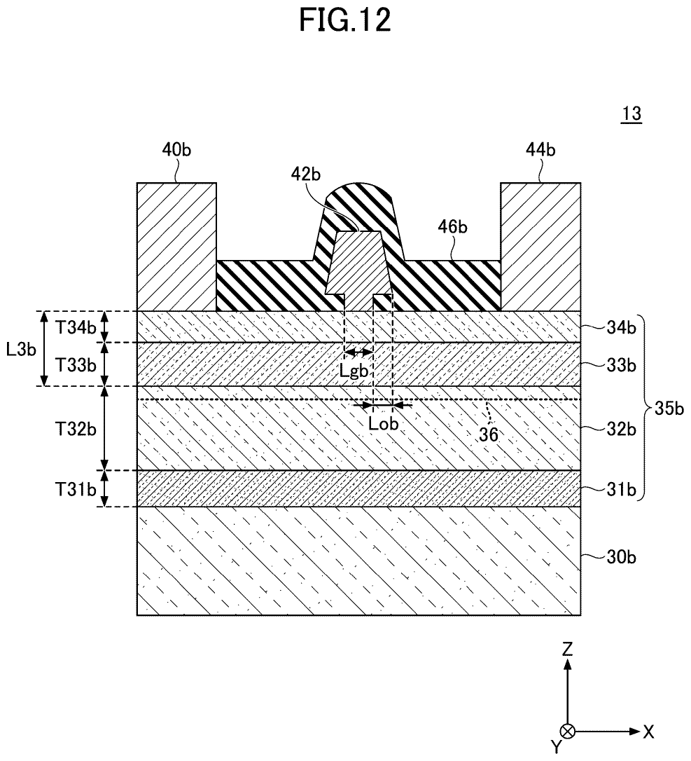

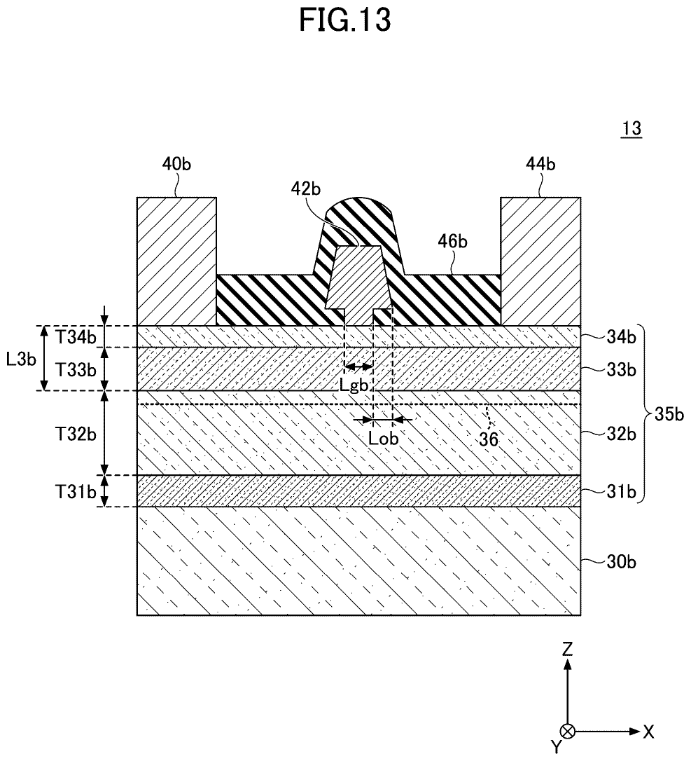

FIG. 12 is a cross-sectional view showing the structural example 2 of the field effect transistor 13. As shown in FIG. 12, the thickness T31b of the nucleation layer 31b of the field effect transistor 13 is larger than the thickness T31a of the nucleation layer 31a of the field effect transistor 11 in FIG. 10. The thickness, size, material, and the like of each of the other layers are the same as those of the field effect transistor 11 shown in FIG. 10.

As shown in FIG. 10 and FIG. 12, the nucleation layer 31a is thinner than the nucleation layer 31b. The nucleation layers 31a and 31b are made of aluminum nitride, and the buffer layers 32a and 32b are made of gallium nitride. Thus, the band gap energy of the nucleation layers 31a and 31b is larger than the band gap energy of the buffer layers 32a and 32b. Thus, the energy at the bottom of the conduction band in the buffer layer 32a near the two dimensional electron gas 36 in the field effect transistor 11 having the small thickness T31a is lower than the energy at the bottom of the conduction band in the buffer layer 32b near the two dimensional electron gas 36 in the field effect transistor 13. Thus, the drain conductance Gd1 of the field effect transistor 11 can be made larger than Gd3.

The thickness T31a is, for example, equal to or less than 0.98 times, equal to or less than 0.95 times, and equal to or less than 0.9 times the thickness T31b. When the thickness T31a of the field effect transistor 11 is too small, it is difficult to form the buffer layer 32a. From this viewpoint, the thickness T31a can be equal to or more than 0.5 times the thickness T31b.

### (Structural Example 3 of Field Effect Transistor 13)

FIG. 13 is a cross-sectional view showing the structural example 3 of the field effect transistor 13. As shown in FIG. 13, a thickness T34b of the cap layer 34b of the field effect transistor 13 is smaller than the thickness T34a of the cap layer 34a of the field effect transistor 11 in FIG. 10. Thus, a distance L3b of the field effect transistor 13 is smaller than the distance L3a of the field effect transistor 11. The thickness, size, material, and the like of each of the other layers are the same as those of the field effect transistor 11 shown in FIG. 10.

As shown in FIG. 10 and FIG. 13, the distance L3a of the field effect transistor 11 is larger than the distance L3b of the field effect transistor 13. As the aspect ratios (that is, L3a/Lga and L3b/Lgb) of the regions directly below the gate electrodes 42a and 42b increase, the drain conductance increases. Thus, the drain conductance Gd1 of the field effect transistor 11 can be made larger than Gd3.

The distance L3a is, for example, equal to or more than 1.05 times, equal to or more than 1.1 times, and equal to or more than 1.2 times the distance L3b. When the distance L3a is too large, the drain conductance Gd1 of the field effect transistor 11 becomes too large, and the high frequency characteristics deteriorate. From this viewpoint, the distance L3a can be equal to or less than twice the distance L3b. Although the example in which the thicknesses T33a and T33b are the same has been described, the thickness T33a may be larger than T33b.

### (Structural Example 4 of Field Effect Transistor 13)

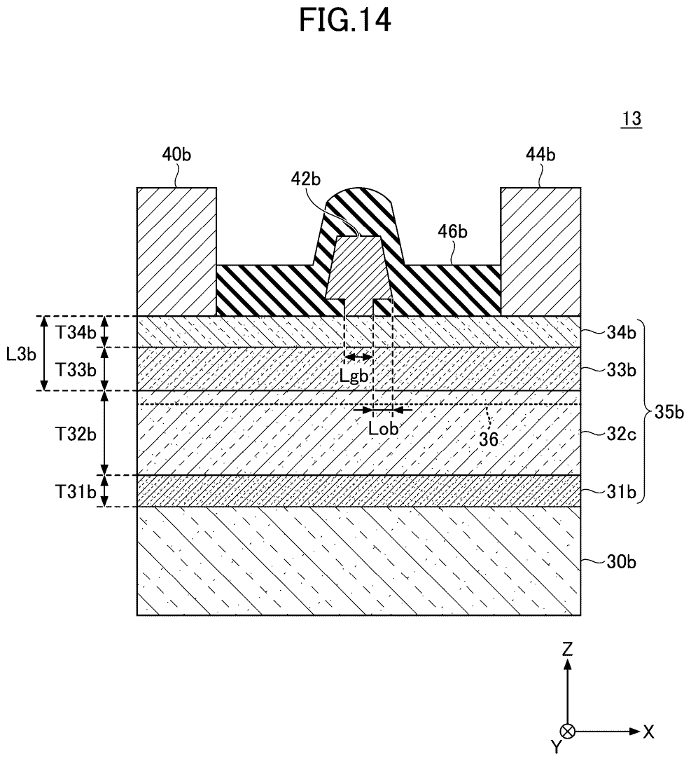

FIG. 14 is a cross-sectional view showing a structural example 4 of the field effect transistor 13. As shown in FIG. 14, the carbon concentration of the buffer layer 32b of the field effect transistor 13 is higher than the carbon concentration of the buffer layer 32a of the field effect transistor 11 in FIG. 10. The thickness, size, material, and the like of each of the other layers are the same as those of the field effect transistor 11 shown in FIG. 10.

As shown in FIG. 10 and FIG. 14, the carbon concentration of the buffer layer 32a is lower than the carbon concentration of the buffer layer 32b. In the nitride semiconductor layer, carbon functions as an acceptor. Thus, the energy at the bottom of the conduction band in the buffer layer 32a near the two dimensional electron gas 36 in the field effect transistor 11 having a low carbon concentration is lower than the energy at the bottom of the conduction band in the buffer layer 32b near the two dimensional electron gas 36 in the field effect transistor 13. Thus, the drain conductance Gd1 of the field effect transistor 11 can be made larger than Gd3.

The carbon concentration of the buffer layer 32a is, for example, equal to or less than half, equal to or less than one-fifth, or equal to or less than one-tenth of the carbon concentration of the buffer layer 32b. When the carbon concentration of the buffer layer 32a is too low, the drain conductance Gd1 of the field effect transistor 11 becomes too large, and the high frequency characteristics deteriorate. From this viewpoint, the carbon concentration of the buffer layer 32a can be equal to or more than one-hundredth of the carbon concentration of the buffer layer 32b. The carbon concentration of the buffer layer 32a is, for example, 1×10¹⁵ cm⁻³ to 1×10¹⁸ cm⁻³, and the carbon concentration of the buffer layer 32b is, for example, 1×10¹⁵ cm⁻³ to 1×10¹⁸ cm⁻³. The difference between the carbon concentration of the buffer layer 32b and the carbon concentration of the buffer layer 32a is, for example, 1×10¹⁶ cm⁻³ or more, 2×10¹⁶ cm⁻³ or more, and 5×10¹⁶ cm⁻³ or more.

### (Structural Example 5 of Field Effect Transistor 13)

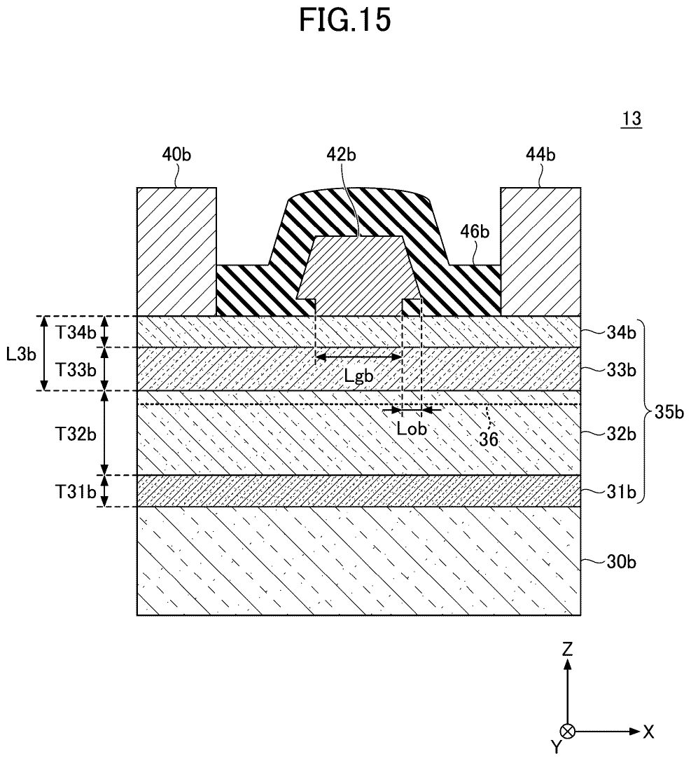

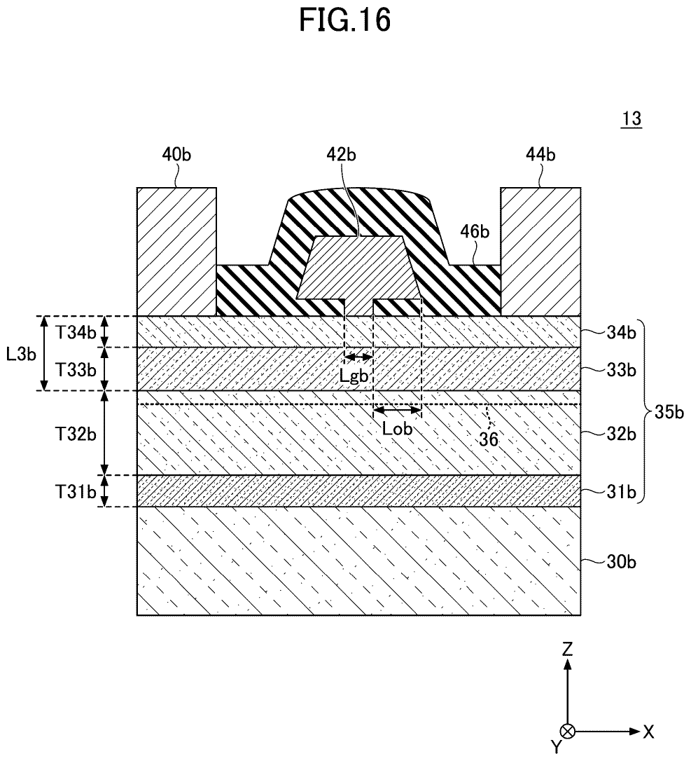

FIG. 15 is a cross-sectional view showing the structural example 5 of the field effect transistor 13. As shown in FIG. 15, a gate length Lgb of the field effect transistor 13 is larger than the gate length Lga of the field effect transistor 11 of FIG. 10. The thickness, size, material, and the like of each of the other layers are the same as those of the field effect transistor 11 shown in FIG. 10.

As shown in FIG. 10 and FIG. 15, the gate length Lga of the field effect transistor 11 is shorter than the gate length Lgb of the field effect transistor 13. As the gate length becomes shorter, the drain conductance becomes larger. Thus, the drain conductance Gd1 of the field effect transistor 11 can be made larger than Gd3.

The gate length Lga is, for example, equal to or less than 0.95 times, equal to or less than 0.9 times, and equal to or less than 0.8 times the gate length Lgb. When the gate length Lga is too short, the drain conductance Gd1 of the field effect transistor 11 becomes too large, and the high-frequency characteristics deteriorate. From this viewpoint, the gate length Lga can be equal to or more than 0.5 times the gate length Lgb. The difference between the gate length Lga and the gate length Lgb is, for example, 50 nm or more, 100 nm or more, or 200 nm or more.

### (Structural Example 6 of Field Effect Transistor 13)

FIG. 16 is a cross-sectional view showing a structural example 6 of the field effect transistor 13. As shown in FIG. 16, an overhang length Lob of the field effect transistor 13 is larger than the overhang length Loa of the field effect transistor 11 of FIG. 10. The thickness, size, material, and the like of each of the other layers are the same as those of the field effect transistor 11 shown in FIG. 10.

As shown in FIG. 10 and FIG. 16, the overhang length Loa of the field effect transistor 11 is shorter than the overhang length Lob of the field effect transistor 13. The potential of the upper surfaces of the nitride semiconductor layers 35a and 35b under the overhanging gate electrodes 42a and 42b becomes close to the gate potential, the electric field in the nitride semiconductor layers 35a and 35b is alleviated, and the drain conductance is reduced. Thus, the drain conductance Gd1 of the field effect transistor 11 having the short overhang length Loa is increased. Thus, the drain conductance Gd1 of the field effect transistor 11 can be made larger than Gd3.

The overhang length Loa is, for example, equal to or less than 0.95 times, equal to or less than 0.9 times, and equal to or less than 0.8 times the overhang length Lob. When the overhang length Loa is too short, the drain conductance Gd1 of the field effect transistor 11 becomes too large, and the high-frequency characteristics deteriorate. From this viewpoint, the overhang length Loa can be equal to or more than 0.5 times the overhang length Lob. The difference between the overhang lengths Loa and Lob is, for example, 50 nm or more, 100 nm or more, or 200 nm or more.

### (Structural Example 7 of Field Effect Transistor 13)

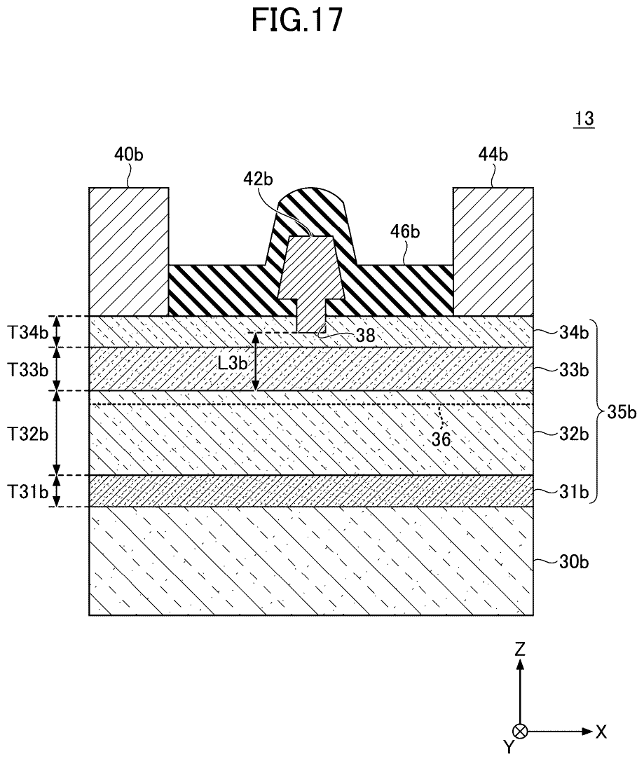

FIG. 17 is a cross-sectional view showing a structural example 7 of the field effect transistor 13. As shown in FIG. 17, a recess 38 is provided on the upper surface of the nitride semiconductor layer 35b. The bottom surface of the recess 38 is located in the cap layer 34b and does not reach the electron supply layer 33b. The gate electrode 42b is in contact with the nitride semiconductor layer 35b in the recess 38. The thickness, size, material, and the like of each of the other layers are the same as those of the field effect transistor 11 shown in FIG. 10.

As shown in FIG. 10 and FIG. 17, when the recess 38 is provided in the field effect transistor 13, the distance L3a of the field effect transistor 11 is larger than the distance L3b of the field effect transistor 13. This increases L3a/Lga, which is the aspect ratio of the field effect transistor 11, and increases the drain conductance Gd1. Thus, the drain conductance Gd1 of the field effect transistor 11 can be made larger than Gd3.

The recess 38 may be provided in the field effect transistor 11 as well. When the recess depth in the case where the recess 38 is not provided is 0 nm, the difference between the recess depth of the field effect transistor 13 and the recess depth of the field effect transistor 11 is, for example, 5 nm or more, 10 nm or more, or 20 nm or more. The recess 38 may reach the electron supply layer 33b.

### (Structural Example 8 of Field Effect Transistor 13)

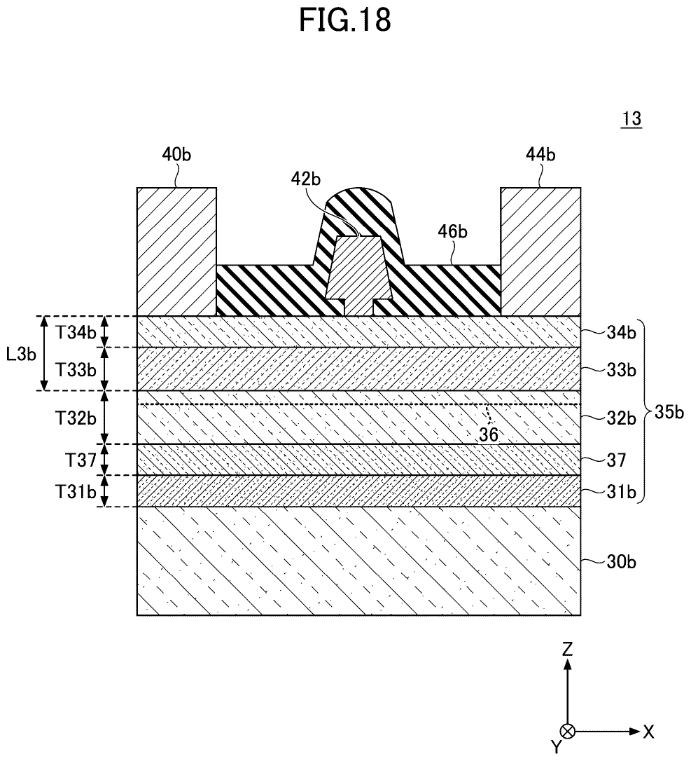

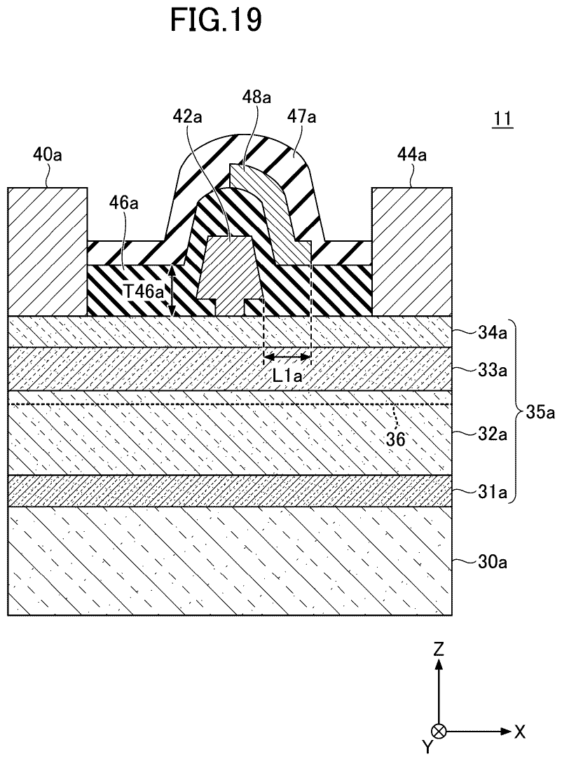

FIG. 18 is a cross-sectional view showing a structural example 8 of the field effect transistor 13. As shown in FIG. 18, a buffer layer 37 is provided between the nucleation layer 31b and the buffer layer 32b. The band gap energy of the buffer layer 37 is larger than the band gap energy of the buffer layer 32b. When the buffer layer 32b is a gallium nitride layer, the buffer layer 37 is, for example, an aluminum gallium nitride layer. The sum of the thicknesses T37 and T32b of the buffer layer 37 is substantially the same as the thickness T32a of FIG. 10.

As shown in FIG. 18, when the buffer layer 37 is provided, the energy at the bottom of the conduction band in the buffer layer 32b near the two dimensional electron gas 36 in the field effect transistor 13 is higher than the energy at the bottom of the conduction band in the buffer layer 32a near the two dimensional electron gas 36 in the field effect transistor 11. Thus, the drain conductance Gd1 of the field effect transistor 11 can be made larger than Gd3.

### (Structural Example 2 of Field Effect Transistor 11)

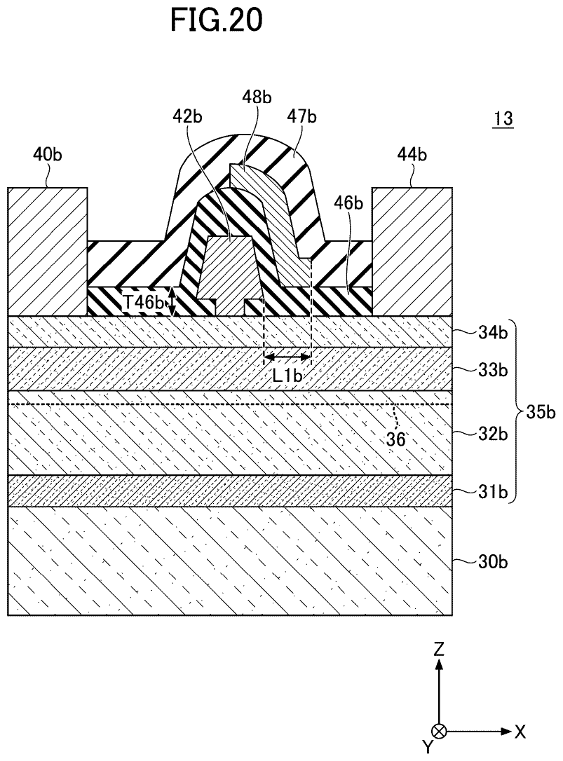

FIG. 19 is a cross-sectional view showing the structural example 2 of the field effect transistor 11. As shown in FIG. 19, a field plate 48a (first field plate) is provided on the insulating layer 46a from above the gate electrode 42a to above a region between the gate electrode 42a and the drain electrode 44a. An insulating layer 47a is provided on the insulating layer 46a so as to cover the field plate 48a. The other configuration is the same as that of the structural example 1 of the field effect transistor 11 shown in FIG. 10.

### (Structural Example 9 of Field Effect Transistor 13)

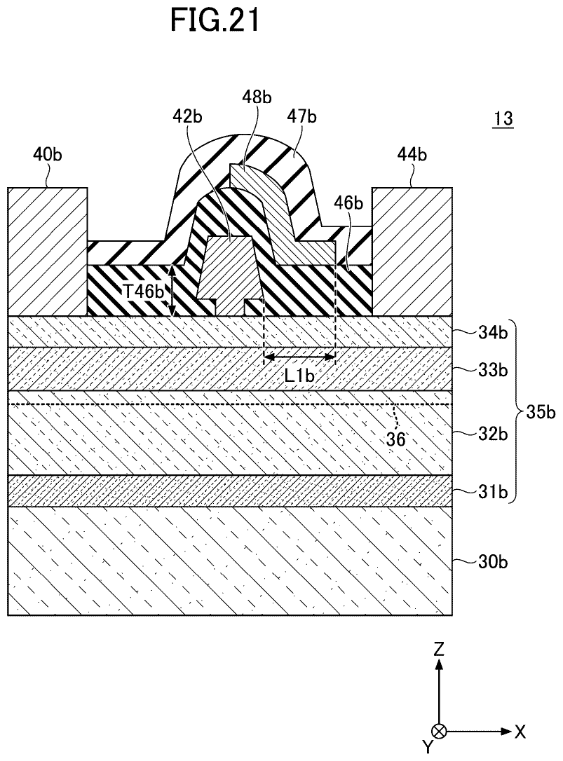

FIG. 20 is a cross-sectional view showing a structural example 9 of the field effect transistor 13. As shown in FIG. 20, in the field effect transistor 13, a field plate 48b (second field plate) is provided on the insulating layer 46b, and an insulating layer 47b is provided so as to cover the field plate 48b. A thickness T46b of the insulating layer 46b is smaller than a thickness T46a of the insulating layer 46a in FIG. 19. The other configuration is the same as that of the structural example 2 of the field effect transistor 11 shown in FIG. 19.

The field plates 48a and 48b are metal layers such as gold films. The insulating layers 47a and 47b are inorganic insulator layers such as silicon nitride layers. The thicknesses T46a and T46b correspond to the distances between the nitride semiconductor layers 35a and 35b and the field plates 48a and 48b in the Z direction. The distances L1a and L1b are distances between the ends of the gate electrodes 42a and 42b close to the drain electrodes 44a and 44b and the ends of the field plates 48a and 48b close to the drain electrodes 44a and 44b. The thicknesses T46a and T46b are, for example, 50 nm to 500 nm, and are 200 nm as an example. The distances L1a and L1b are, for example, 0.5 μm to 2.5 μm, and are 1.0 μm as an example.

The field plates 48a and 48b are electrically connected to the source electrodes 40a and 40b, and the same potential as that of the source electrodes 40a and 40b is supplied to the field plates 48a and 48b. When the field plates 48a and 48b are provided, the potential of the upper surfaces of the nitride semiconductor layers 35a and 35b under the field plates 48a and 48b becomes close to the source potential, the electric field in the nitride semiconductor layers 35a and 35b is alleviated, and the drain conductance is reduced. It is sufficient that the field plates 48a and 48b are provided above the nitride semiconductor layers 35a and 35b between the gate electrodes 42a and 42b and the drain electrodes 44a and 44b, and these field plates 48a and 48b may not be provided above the gate electrodes 42a and 42b.

As shown in FIG. 19 and FIG. 20, the thickness T46a of the insulating layer 46a is larger than the thickness T46b of the insulating layer 46b. This makes it possible to make the drain conductance Gd1 of the field effect transistor 11 larger than Gd3.

The thickness T46a is, for example, equal to or more than 1.05 times, equal to or more than 1.1 times, and equal to or more than 1.2 times the thickness T46b. When the thickness T46b is too small, a leakage current is likely to flow between the field plate 48b and the nitride semiconductor layer 35b in the field effect transistor 13. From this viewpoint, the thickness T46a can be equal to or less than twice the thickness T46b.

### (Structural Example 10 of Field Effect Transistor 13)

FIG. 21 is a cross-sectional view showing a structural example 10 of the field effect transistor 13. As shown in FIG. 21, a distance L1b of the field effect transistor 13 is larger than the distance L1a of the field effect transistor 11 in FIG. 19. The thickness, size, material, and the like of each of the other layers are the same as those of the field effect transistor 11 of FIG. 19.

As shown in FIG. 19 and FIG. 21, the distance L1a of the field effect transistor 11 is smaller than the distance L1b of the field effect transistor 13. This alleviates the electric field in the nitride semiconductor layers 35a and 35b, and the drain conductance Gd1 of the field effect transistor 11 can be made larger than Gd3.

The distance L1a is, for example, equal to or less than 0.95 times, equal to or less than 0.9 times, and equal to or less than 0.8 times the distance L1b. When the distance L1a is too short, the field plate 48a does not function. From this viewpoint, the distance L1a can be equal to or more than 0.5 times the distance L1b. The difference between the distances L1a and L1b is, for example, 50 nm or more, 100 nm or more, or 200 nm or more.

At least two of the structural example 1 to the structural example 10 of the field effect transistor 13 may be used in combination. For example, when the structural example 1 and the structural example 2 of the field effect transistor 13 are used in combination, the thickness T32a of the buffer layer 32a of the field effect transistor 11 is larger than the thickness T32b of the buffer layer 32b of the field effect transistor 13, and the thickness T31a of the nucleation layer 31a of the field effect transistor 11 is smaller than the thickness T31b of the nucleation layer 31b of the field effect transistor 13.

### [Example 1 of Semiconductor Device]

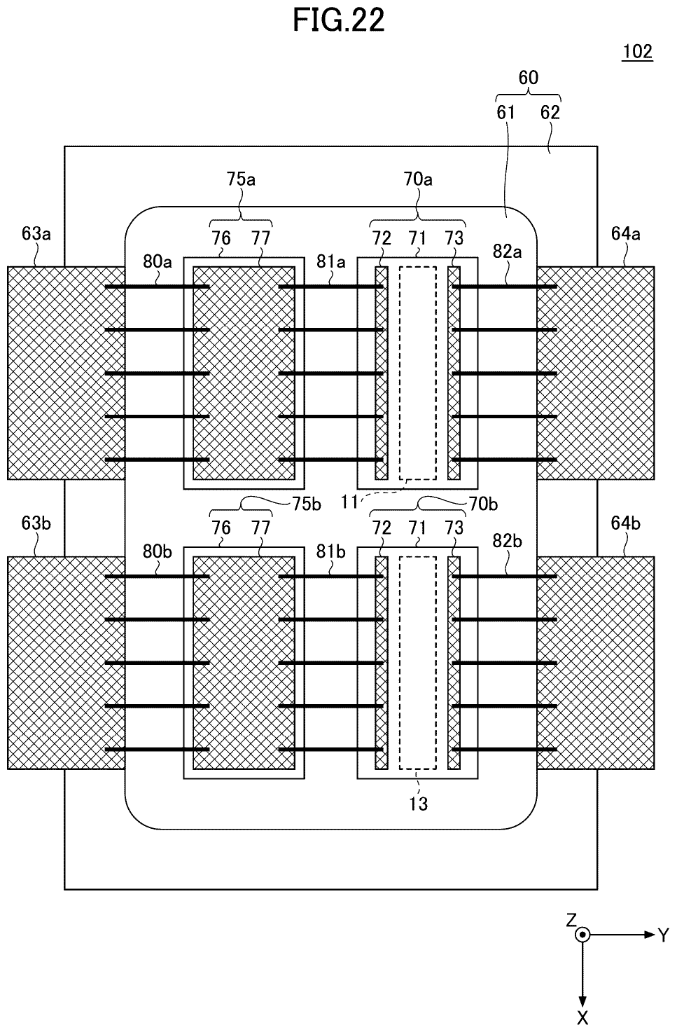

FIG. 22 is a plan view showing an example 1 of the semiconductor device used in the first embodiment. The thickness direction of a base 61 is defined as a Z direction, the arrangement direction from the leads 63a and 63b to the leads 64a and 64b is defined as a Y direction, and the direction intersecting the Z direction and the Y direction is defined as an X direction. As shown in FIG. 22, in semiconductor device 102, a package 60 includes the base 61 and a frame body 62. At least the upper surface of the base 61 is electrically conductive, and the base 61 is, for example, a laminate of a copper layer and a molybdenum layer. The frame body 62 is an inorganic insulating layer such as an alumina layer. The leads 63a and 63b are arranged in the X direction on the side of the frame body 62 in the negative Y direction. The leads 64a and 64b are provided on the side of the frame body 62 in the positive Y direction. The leads 63a, 63b, 64a, and 64b are metal plates such as copper plates.

A capacitance component 75a and a semiconductor chip 70a are mounted on the base 61 between the leads 63a and 64a. A capacitance component 75b and a semiconductor chip 70b are mounted on the base 61 between the leads 63b and 64b. The semiconductor chip 70a includes a substrate 71, and the field effect transistor 11, pads 72 and 73 provided on the substrate 71. The semiconductor chip 70b includes the substrate 71, and the field effect transistor 13, the pads 72 and 73 provided on the substrate 71. An electrode (not shown) is provided on the lower surface of the substrate 71. The pads 72 and 73 and the electrode on the lower surface of the substrate 71 are electrically connected to the gate electrode, the drain electrode, and the source electrode of the field effect transistors 11 and 13, respectively. The electrode on the lower surface of the substrate 71 is electrically connected to the base 61 and short-circuited. The substrate 71 is, for example, a semiconductor substrate, and is, a for example, silicon carbide substrate when the field effect transistors 11 and 13 are GaN HEMTs. The pads 72 and 73 and the electrode on the lower surface of the substrate 71 are metal layers such as gold layers and copper layers.

Each of the capacitance components 75a and 75b includes a substrate 76, an electrode 77 provided on the upper surface of the substrate 76, and an electrode (not shown) provided on the lower surface of the substrate 76. The substrate 76, the electrode 77 and the electrode on the lower surface of the substrate 76 form a capacitor, the electrodes sandwiching the substrate 76. The electrode on the lower surface of the substrate 76 is electrically connected to the base 61 and short-circuited. The substrate 76 is a dielectric substrate such as an aluminum oxide substrate or a barium titanate substrate. The electrode 77 and the electrode on the lower surface of the substrate 76 are metal layers such as gold layers and copper layers.

Bonding wires 80a and 80b electrically connect the leads 63a and 63b to the electrodes 77 the capacitance components 75a and 75b, of respectively. Bonding wires 81a and 81b electrically connect the electrodes 77 of the capacitance components 75a and 75b to the pads 72 of the semiconductor chips 70a and 70b, respectively. The bonding wires 82a and 82b electrically connect the pads 73 of the semiconductor chips 70a and 70b to the leads 64a and 64b, respectively. The bonding wires 80a, 80b, 81a, 81b, 82a, and 82b are metal wires such as gold wires or aluminum wires. The bonding wires 80a, 81a and the capacitance component 75a form a T-shaped circuit of the LCL, which is at least a part of the matching circuit 20 of FIG. 1. The bonding wires 80b and 81b and the capacitance component 75b form a T-shaped circuit of the LCL, which is at least a part of the matching circuit 21 of FIG. 1.

The signals S1 and S2 input from the leads 63a and 63b reach the pads 72 of the semiconductor chips 70a and 70b via the capacitance components 75a and 75b, respectively. The signals S3 and S4 output from the pads 73 of the semiconductor chips 70a and 70b are output from the leads 64a and 64b, respectively.

In the example of the semiconductor device, the field effect transistors 11 and 13 are provided on different substrates 71. Thus, the structural examples 1 to 10 can be appropriately used as the field effect transistor 13. As shown in the amplifier D of f Table 1, since the field effect transistors 11 and 13 are different, a balance between distortion and efficiency becomes possible.

### [Example 2 of Semiconductor Device]

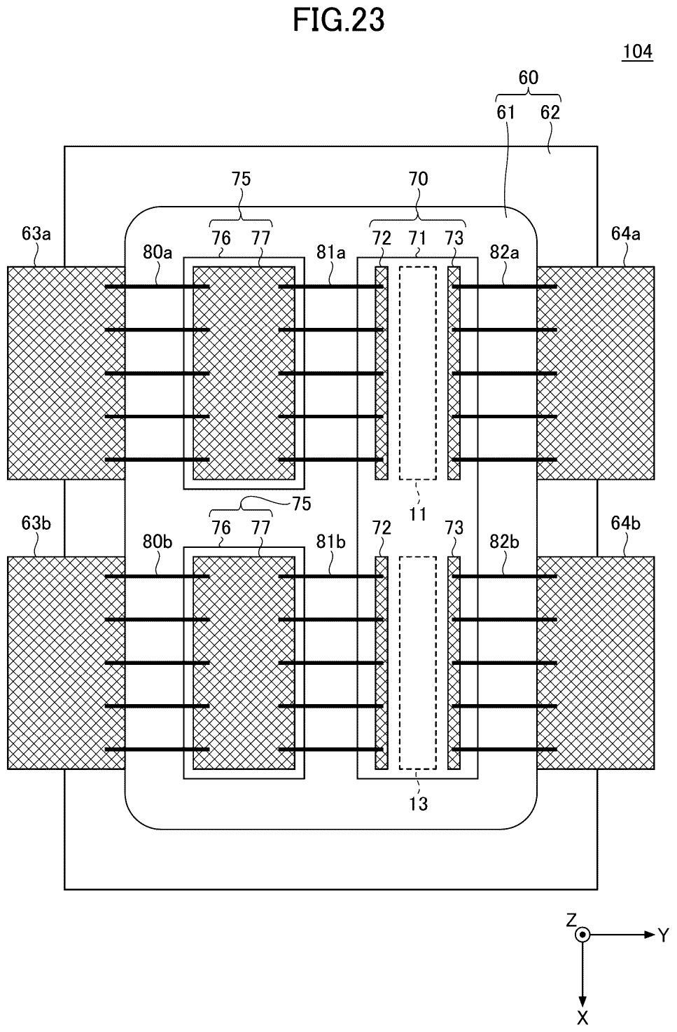

FIG. 23 is a plan view showing an example 2 of the semiconductor device used in the first embodiment. As shown in FIG. 23, in a semiconductor device 104, the field effect transistors 11 and 13 are provided in a same semiconductor chip 70. The other configuration is the same as that of the semiconductor device example 1, and the description thereof is omitted. In the semiconductor device example 2, it is difficult to adopt a structure different from that of the nitride semiconductor layer 35a of the field effect transistor 11 as the nitride semiconductor layer 35b as in the structural example 1 to the structural example 4 of the field effect transistor 13. As in structural example 5 to structural example 10 of the field effect transistor 13, when the same structure as the nitride semiconductor layer 35a is adopted as the nitride semiconductor layer 35b, the semiconductor device can be easily achieved.

In the example 1 and the example 2 of the semiconductor device, the example in which the semiconductor chips 70a and 70b or 70 are mounted on the package 60 has been described, but the semiconductor device may be a module in which the semiconductor chips 70a and 70b or 70 are mounted on a circuit in which at least a part of the divider 14, the combiner 16, and the matching circuits 20 to 23 is formed. Further, the semiconductor device may be a monolithic microwave integrated circuit (MMIC) in which at least a part of the field effect transistors 11 and 13, the divider 14, the combiner 16, and the matching circuits 20 to 23 is provided on the substrate 71.

Although the 2-way Doherty amplifier provided with one peak amplifier 12 has been described as an example of the Doherty amplifier, the Doherty amplifier may be an N-way amplifier circuit (N is two or more) provided with two or more peak amplifiers 12. When two or more peak amplifiers 12 are provided, it is sufficient that at least one of the plurality of peak amplifiers 12 has any one of the structural example 1 to the structural example 10 of the field effect transistor 13.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. A semiconductor device for a Doherty amplifier comprising:
a main amplifier including a first field effect transistor including:
a first nitride semiconductor layer,
a first source electrode,
a first gate electrode, and
a first drain electrode, the first source electrode, the first gate electrode, and the first drain electrode being provided on the first nitride semiconductor layer, and the main amplifier being configured to amplify a first signal distributed from an input signal; and
a peak amplifier including a second field effect transistor including:
a second nitride semiconductor layer,
a second source electrode,
a second gate electrode, and
a second drain electrode, the second source electrode, the second gate electrode, and the second drain electrode being provided on the second nitride semiconductor layer, and the peak amplifier being configured to amplify a second signal distributed from the input signal,
wherein a first drain conductance of the first field effect transistor when applying a gate voltage obtained by adding a predetermined voltage to a pinch-off voltage and a predetermined drain voltage is larger than a second drain conductance of the second field effect transistor when applying both the gate voltage and the predetermined drain voltage, such that when measuring the first drain conductance, the drain current having a same value as a drain current flowing through the first field effect transistor flows through the second field effect transistor.

2. The semiconductor device according to claim 1,
wherein the first nitride semiconductor layer includes a first buffer layer provided over a first substrate and a first electron supply layer provided on the first buffer layer,
the second nitride semiconductor layer includes a second buffer layer provided over a second substrate and a second electron supply layer provided on the second buffer layer, and
the first buffer layer is thicker than the second buffer layer.

3. The semiconductor device according to claim 1,
wherein the first nitride semiconductor layer includes a first aluminum nitride layer provided on a first substrate, a first gallium nitride buffer layer provided on the first aluminum nitride layer, and a first electron supply layer provided on the first gallium nitride buffer layer,
the second nitride semiconductor layer includes a second aluminum nitride layer provided on a second substrate, a second gallium nitride buffer layer provided on the second aluminum nitride layer, and a second electron supply layer provided on the second gallium nitride buffer layer, and
the first aluminum nitride layer is thinner than the second aluminum nitride layer.

4. The semiconductor device according to claim 1,
wherein the first nitride semiconductor layer includes a first buffer layer provided over a first substrate and a first electron supply layer provided on the first buffer layer,
the second nitride semiconductor layer includes a second buffer layer provided over a second substrate and a second electron supply layer provided on the second buffer layer, and
a distance between the first buffer layer and the first gate electrode in a thickness direction of the first nitride semiconductor layer is larger than a distance between the second buffer layer and the second gate electrode in a thickness direction of the second nitride semiconductor layer.

5. The semiconductor device according to claim 1,
wherein the first nitride semiconductor layer includes a first buffer layer provided over a first substrate and a first electron supply layer provided on the first buffer layer,
the second nitride semiconductor layer includes a second buffer layer provided over a second substrate and a second electron supply layer provided on the second buffer layer, and
a carbon concentration of the first buffer layer is lower than a carbon concentration of the second buffer layer.

6. The semiconductor device according to claim 1,
wherein a gate length of the first gate electrode is shorter than a gate length of the second gate electrode.

7. The semiconductor device according to claim 1,
wherein the first gate electrode overhangs at least toward the first drain electrode, the second gate electrode overhangs at least toward the second drain electrode, and a length of the first gate electrode overhanging toward the first drain electrode is shorter than a length of the second gate electrode overhanging toward the second drain electrode.

8. The semiconductor device according to claim 1,
wherein the first field effect transistor includes a first field plate provided above the first nitride semiconductor layer between the first gate electrode and the first drain electrode,
the second field effect transistor includes a second field plate provided above the second nitride semiconductor layer between the second gate electrode and the second drain electrode, and
a distance between the first nitride semiconductor layer and the first field plate in a thickness direction of the first nitride semiconductor layer is larger than a distance between the second nitride semiconductor layer and the second field plate in a thickness direction of the second nitride semiconductor layer.

9. The semiconductor device according to claim 1,
wherein the first field effect transistor includes a first field plate provided above the first nitride semiconductor layer between the first gate electrode and the first drain electrode,
the second field effect transistor includes a second field plate provided above the second nitride semiconductor layer between the second gate electrode and the second drain electrode, and
a distance between an end of the first gate electrode close to the first drain electrode and an end of the first field plate close to the first drain electrode is shorter than a distance between an end of the second gate electrode close to the second drain electrode and an end of the second field plate close to the second drain electrode.

10. A Doherty amplifier comprising:
the semiconductor device of claim 1;
a divider configured to divide the input signal into the first signal and the second signal; and
a combiner configured to combine the first signal amplified by the main amplifier and the second signal amplified by the peak amplifier.
